(19) United States
(12) Patent Application Publication
(10) Pub. No.: US 2019/0103522 A1
(43) Pub. Date: Apr. 4, 2019

(54) LIGHTING APPARATUS AND LIGHT EMITTING APPARATUS

(71) Applicant: PANASONIC INTELLECTUAL PROPERTY MANAGEMENT CO., LTD., Osaka (JP)

(72) Inventors: Masumi ABE, Osaka (JP); Toshiaki KURACHI, Kyoto (JP); Yuya YAMAMOTO, Osaka (JP); Koji OMURA, Osaka (JP); Kosuke TAKEHARA, Osaka (JP)

(73) Assignee: PANASONIC INTELLECTUAL PROPERTY MANAGEMENT CO., LTD., Osaka (JP)

(21) Appl. No.: 16/141,320

(22) Filed: Sep. 25, 2018

(30) Foreign Application Priority Data
Sep. 26, 2017 (JP) 2017-185132
Feb. 20, 2018 (JP) 2018-028309

(51) Int. Cl. H01L 33/50; H05B 33/08

(52) U.S. Cl. CPC H01L 33/502; H05B 33/0845

(57) ABSTRACT

A lighting apparatus includes an LED chip that emits primary light, and phosphor particles that emit secondary light by being excited with the primary light. The lighting apparatus emits light including the primary light and the secondary light. The light has an emission spectrum having a first peak in a wavelength ranging from 420 nm to 460 nm, a second peak in the wavelength ranging from 530 nm to 580 nm, a third peak in the wavelength ranging from 605 nm to 655 nm, a first trough in the wavelength ranging from 440 nm to 480 nm, and a second trough in the wavelength ranging from 555 nm to 605 nm.

### CROSS REFERENCE TO RELATED APPLICATION

This application claims the benefit of priority of Japanese Patent Application Number 2017-185132, filed Sep. 26, 2017 and Japanese Patent Application Number 2018-028309, filed Feb. 20, 2018. The entire content of which is hereby incorporated by reference.

### FIELD

The present disclosure relates to a lighting apparatus.

### BACKGROUND

Conventionally, a light emitting apparatus that emits light different from the light emitted by light emitting diode (LED) chips through combining light emitting elements such as LED chips and phosphor particles that emit light by being excited by the light emitted from the LED chips is known. In Patent Literature (PTL) 1, a light emitting apparatus with enhanced emission efficiency in which a decrease in brightness along with a rise in temperature does not occur easily is disclosed as an example of such a light emitting apparatus.

### CITATION LIST

### Patent Literature

### [PTL1]

Japanese Unexamined Patent Application Publication No. 2011-134934.

### SUMMARY

### Technical Problem

White light emitted by the lighting apparatus using light emitting elements such as LEDs has a poorer color reproduction than natural light due to light intensity deviations in an emission spectrum. In other words, enhancing the color reproduction of such a lighting apparatus poses a challenge.

The present disclosure provides a lighting apparatus in which the color reproduction is enhanced.

### Solution to Problem

A lighting apparatus according to an aspect of the present disclosure includes a light emitting element that emits primary light, and light emitting particles that emit secondary light by being excited with the primary light. The lighting apparatus emits light including the primary light and the secondary light. The light has an emission spectrum having a first peak in a wavelength ranging from 420 nm to 460 nm, a second peak in the wavelength ranging from 530 nm to 580 nm, a third peak in the wavelength ranging from 605 nm to 655 nm, a first trough in the wavelength ranging from 440 nm to 480 nm, and a second trough in the wavelength ranging from 555 nm to 605 nm.

A light emitting apparatus according to an aspect of the present disclosure includes the light emitting element that emits the primary light, and the light emitting particles that emit the secondary light by being excited with the primary light. The lighting apparatus emits light including the primary light and the secondary light. The light has an emission spectrum having the first peak in the wavelength ranging from 420 nm to 460 nm, the second peak in the wavelength ranging from 530 nm to 580 nm, the third peak in the wavelength ranging from 605 nm to 655 nm, the first trough in the wavelength ranging from 440 nm to 480 nm, and the second trough in the wavelength ranging from 555 nm to 605 nm.

### Advantageous Effects

The present disclosure achieves a lighting apparatus in which the color reproduction is enhanced.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is an external perspective view of a lighting apparatus and peripheral components thereof according to Embodiment 1.

FIG. 2 is a cross-sectional view of the lighting apparatus according to Embodiment 1.

FIG. 3 shows a relationship between examples of the lighting apparatus according to Embodiment 1 and color rendering index Ri.

FIG. 4 shows a relationship between examples of the lighting apparatus according to Embodiment 1 and properties of quantum dots used in each of the examples.

FIG. 5 shows an emission spectrum of the lighting apparatus according to Comparative Example 1.

FIG. 6 shows an emission spectrum of the lighting apparatus according to Comparative Example 2.

FIG. 7 shows an emission spectrum of the lighting apparatus according to Comparative Example 3.

FIG. 8 shows an emission spectrum of the lighting apparatus according to Comparative Example 4.

FIG. 9 shows an emission spectrum of the lighting apparatus according to Comparative Example 5.

FIG. 10 shows an emission spectrum of the lighting apparatus according to Comparative Example 6.

FIG. 11 shows an emission spectrum of the lighting apparatus according to Example 1.

FIG. 12 shows an emission spectrum of the lighting apparatus according to Example 2.

FIG. 13 shows an emission spectrum of the lighting apparatus according to Example 3.

FIG. 14 shows an emission spectrum of the lighting apparatus according to Example 4.

FIG. 15 shows an emission spectrum of the lighting apparatus according to Example 5.

FIG. 16 shows an emission spectrum of the lighting apparatus according to Example 6.

FIG. 17 shows an emission spectrum of the lighting apparatus according to Example 7.

FIG. 18 shows an emission spectrum of the lighting apparatus according to Example 8.

FIG. 19 shows the light intensity ratio of a second peak, third peak, first trough, and second trough to a first peak.

FIG. 20 is a plotted graph of the color temperature and the light intensity ratio of the second peak to the first peak.

FIG. 21 is a plotted graph of the color temperature and the light intensity ratio of the third peak to the first peak.

FIG. 22 is a plotted graph of the color temperature and the light intensity ratio of the first trough to the first peak.

FIG. 23 is a plotted graph of the color temperature and the light intensity ratio of the second trough to the first peak.

FIG. 24 shows the color temperature standard established by the American National Standards Institute (ANSI).

FIG. 25 is an external perspective view of a light emitting apparatus according to Embodiment 2.

FIG. 26 is a schematic cross-sectional view of the light emitting apparatus according to Embodiment 2.

FIG. 27 is a schematic cross-sectional view of the light emitting apparatus according to Variation 1 of Embodiment 2.

FIG. 28 is a schematic cross-sectional view of the light emitting apparatus according to Variation 2 of Embodiment 2.

FIG. 29 is a schematic cross-sectional view of the light emitting apparatus according to Variation 3 of Embodiment 2.

FIG. 30 is a schematic cross-sectional view of the light emitting apparatus according to Variation 4 of Embodiment 2.

FIG. 31 is a schematic cross-sectional view of the light emitting apparatus according to Variation 5 of Embodiment 2.

### DESCRIPTION OF EMBODIMENTS

Hereinafter, embodiments will be described with reference to the drawings. Note that each of the embodiments described below shows a comprehensive or specific example. Numerical values, shapes, materials, components, placement and connection of the components, and the like are mere examples and are not intended to limit the present disclosure. Moreover, components in the following embodiments not mentioned in any of the independent claims that define the broadest concepts are described as optional components.

Note that the following drawings are schematic diagrams and do not necessarily provide strictly accurate illustrations. Moreover, in each drawing, components that are substantially the same as components described previous thereto have the same reference numerals and overlapping descriptions may be omitted or simplified.

### Embodiment 1

### (Overall Configuration of Lighting Apparatus)

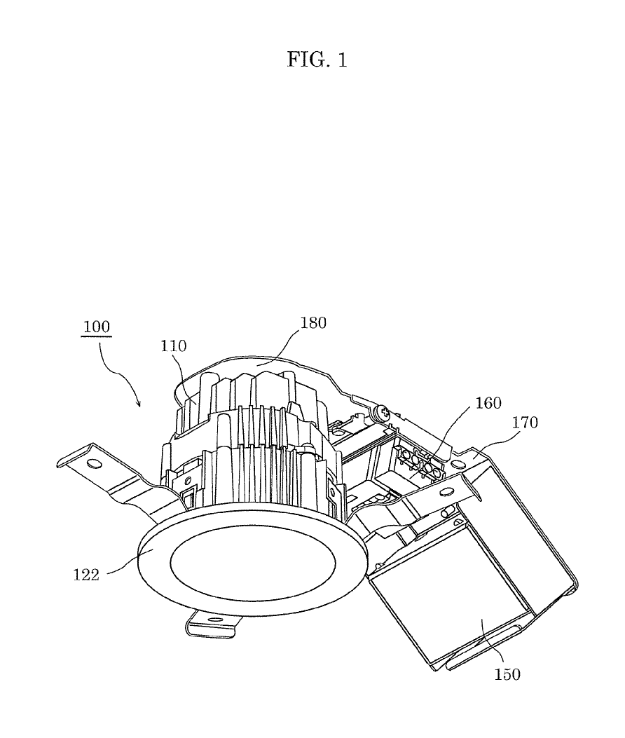

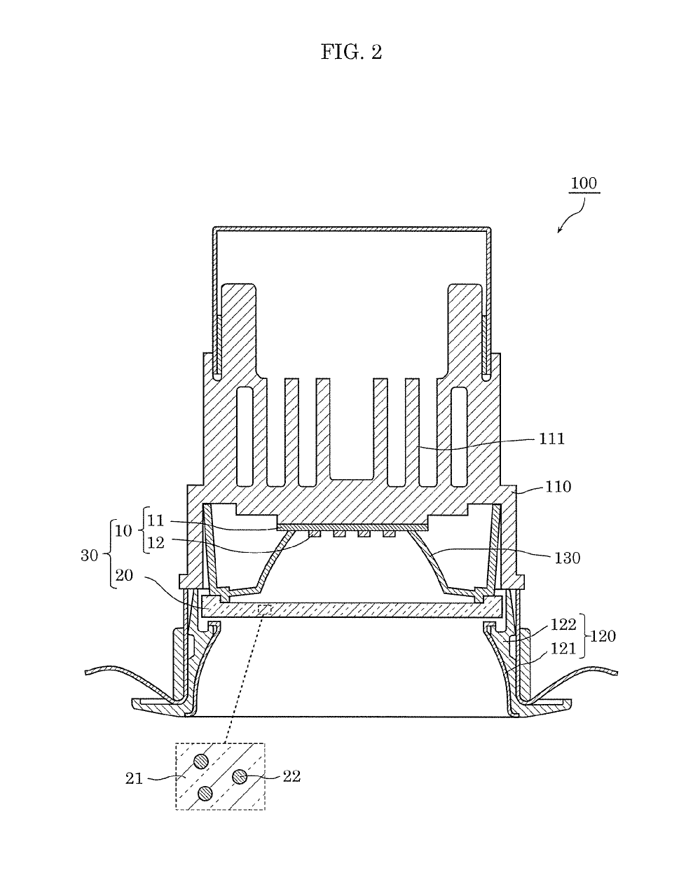

Hereinafter, a lighting apparatus according to Embodiment 1 will be described with reference to the drawings. FIG. 1 is an external perspective view of lighting apparatus 100 according to Embodiment 1. FIG. 2 is a cross-sectional view of lighting apparatus 100 according to Embodiment 1.

As illustrated in FIGS. 1 and 2, lighting apparatus 100 according to Embodiment 1 is, for example, a downlight that emits light downward in a space (corridor, wall or the like) mounted within the ceiling of a home and the like.

Lighting apparatus 100 includes light emitting apparatus 30. Lighting apparatus 100 further includes a substantially bottomed cylindrical fixture body that engages with base unit 110 and frame unit 120, reflection plate 130, lighting device 150, terminal block 160, mounting plate 170, and top plate 180. Light emitting apparatus 30 includes light emitting unit 10 and fluorescent plate 20.

(Light emitting Apparatus: Light emitting Unit)

Light emitting unit 10 is a Chip-on-Board (COB) LED module in which LED chips 12 are directly mounted on substrate 11, and emits blue light.

Substrate 11 has an area in which wires are disposed. The wires supply electric power to LED chips 12 and are made of a metal. Moreover, an electrode for electrically coupling light emitting unit 10 to external devices is also disposed on substrate 11 as part of the above wires. Substrate 11 is, for example, a base metal substrate or ceramic substrate. Substrate 11 may also be a resin substrate mainly made of resin.

The ceramic substrate is, for example, an alumina substrate made of aluminum oxide (alumina), or an aluminum nitride substrate made of aluminum nitride. Moreover, the base metal substrate is, for example, an aluminum alloy substrate, iron alloy substrate, or a copper alloy substrate, which include an insulating film on a surface thereof. The resin substrate is, for example, a glass epoxy substrate made of glass fiber and epoxy resin.

Note that substrate 11 may also, for example, have a high reflectance (for example, 90% or higher). The light emitted by LED chips 12 can be caused to reflect on a surface of substrate 11 when substrate 11 has high reflectance. As a result, light extraction efficiency of light emitting unit 10 is improved. Such a substrate is, for example, a white ceramic substrate mainly made of alumina.

Substrate 11 may also be highly light-transmissive. Such a substrate is, for example, a light-transmissive ceramic substrate made of polycrystalline alumina or aluminum nitride, a transparent glass substrate made of glass, a quartz substrate made of quartz, a sapphire substrate made of sapphire, or a transparent resin substrate made of a transparent resin. Note that substrate 11 is, for example, rectangular in a plan view, but may also be circular or have any other shape.

LED chips 12 are an example of light emitting elements, and are disposed (mounted) on substrate 11. LED chips 12 are, for example, blue LED chips made of a gallium nitride-type material such as indium gallium nitride (InGaN) with a central wavelength (peak wavelength in emission spectrum) ranging from 420 nm to 460 nm. In other words, LED chips 12 emit blue light. In Embodiment 1, LED chips 12 emit blue light with a wavelength peak of approximately 442 nm.

A plurality of LED chips 12 are disposed on substrate 11, but disposing at least one LED chip 12 is sufficient. LED chips 12 may be disposed on substrate 11 in any way. LED chips 12 may also be electrically coupled in any way.

(Light emitting Apparatus: Fluorescent Plate)

Fluorescent plate 20 is an example of a fluorescent component and faces light emitting unit 10. A principal surface of fluorescent plate 20 is perpendicular to an optical axis of light emitting unit 10. Fluorescent plate 20 is disposed along a path of the emission light of light emitting unit 10 at a distance thereof. In other words, fluorescent plate 20 is radiated with blue light emitted by light emitting unit 10. Fluorescent plate 20 is an example of a wavelength-shifting material, and includes base 21 and phosphor particles 22.

Base 21 is, for example, made of a light-transmissive resin such as an acrylic resin or polycarbonate resin, but may also be made of a light-transmissive ceramic material. When base 21 is a resin, phosphor particles 22 are, for example, mixed into the resin during molding. When base 21 is a ceramic material, phosphor particles 22 are, for example, spin-coated on a surface of base 21. Fluorescent plate 20 is, for example, no thicker than 1 mm, but may also be no thicker than 100 μm.

Fluorescent plate 20 may have a laminated structure interposed between glass phosphor layers including phosphor particles 22.

Phosphor particles 22 are an example of light emitting particles, and emit secondary light excited with primary light (i.e., blue light), which is emitted by LED chips 12 included in light emitting unit 10, and that has a longer wavelength than the primary light. Phosphor particles 22 are, for example, quantum dot phosphors including semi-conducting material. The quantum dot phosphors are, to be specific, expressed by the chemical formula CdSₓSe₁₋ₓ/ZnS, but may also be cadmium-free. The quantum dot phosphors can emit light with various wavelength peaks by altering at least one of composition and shape.

When light emitting unit 10 emits the primary light (i.e., blue light), the wavelength of a portion of the primary light is changed to the secondary light by phosphor particles 22 included in fluorescent plate 20. As a result, lighting apparatus 100 emits the primary light not absorbed by phosphor particles 22 and the secondary light whose wavelength is changed by phosphor particles 22. The emission light is, to be specific, white light.

### (Base Unit, Body Unit, Reflection Plate)

Base unit 110 is a mount to which light emitting unit 10 is coupled and a heat sink for dissipating heat generated by light emitting unit 10. Base unit 110 is made of a metal, has a substantially cylindrical shape, and is made of die cast aluminum in Embodiment 1.

Radiator fins 111 are disposed protruding upward and spaced from one another along one direction and at a fixed distance on an upper portion of base unit 110 (portion facing ceiling). This enables the heat generated by light emitting unit 10 to be dissipated efficiently.

Frame unit 120 includes a substantially cylindrical cone unit 121 having a reflective surface on an inner surface, and frame body unit 122 to which cone unit 121 is coupled. Cone unit 121 is made of a metal, and can, for example, be manufactured by raising or stamping an aluminum alloy and the like. Frame body unit 122 is made of a hard resin or metal. Frame unit 120 is fixed by coupling frame body unit 122 to base unit 110.

Reflection plate 130 is cylindrical (funnel-shaped) and an inner surface thereof is reflective. Reflection plate 130 can, for example, be made of a metal such as aluminum. Note that reflection plate 130 may also be made of a hard white resin and not a metal.

### (Lighting Device, Terminal Block, Mounting Plate, Top Plate)

As illustrated in FIG. 1, lighting apparatus 100 includes lighting device 150 that supplies electric power to light emitting unit 10 for turning on light emitting unit 10, and terminal block 160 that relays alternating current to lighting device 150 from a commercial power source. Lighting device 150, to be specific, converts the alternating current relayed from terminal block 160 to direct current, and outputs the direct current to light emitting unit 10.

Lighting device 150 and terminal block 160 are fixed to mounting plate 170 disposed separately from the fixture body. Mounting plate 170 has a bent rectangular shape and is made of a metal. Lighting device 150 is fixed to a lower surface of a longitudinal end portion of mounting plate 170 and terminal block 160 is fixed to another end of the lower surface of the longitudinal end portion of mounting plate 170. Mounting plate 170 and top plate 180, which is fixed to the upper portion of base unit 110 of the fixture body, are joined to each other.

### (Concrete Configuration of Fluorescent Plate in Lighting Apparatus)

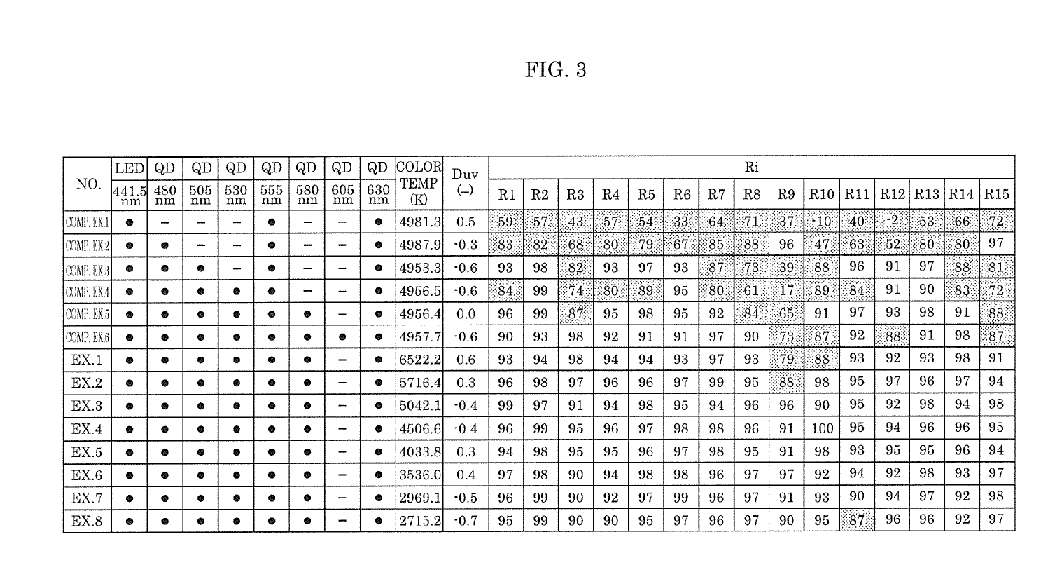

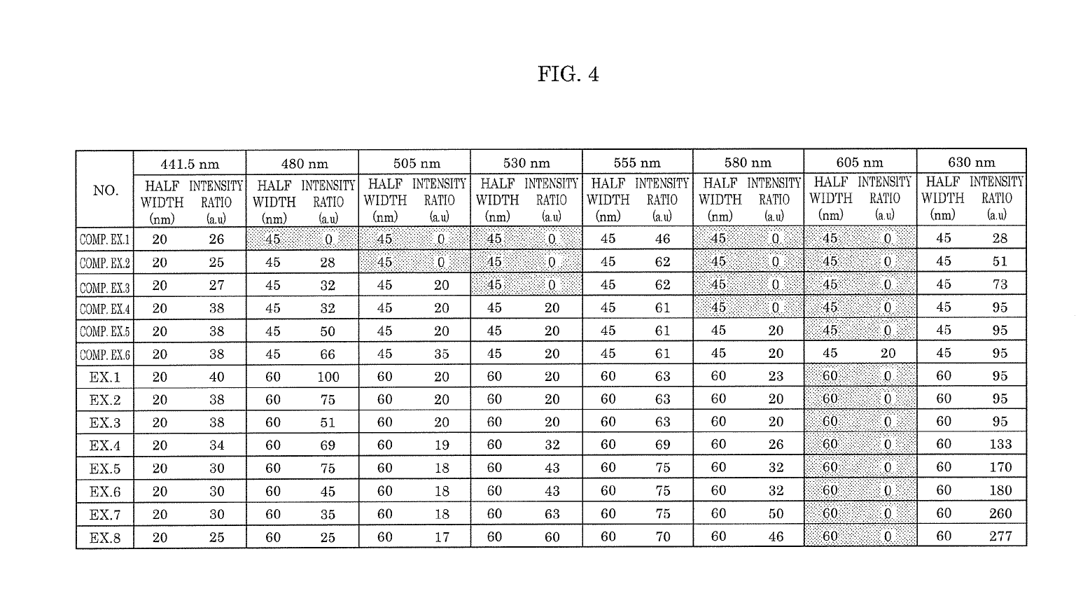

The inventors have achieved lighting apparatus 100 with 15 color rendering indices R1 to R15, each having a high value, by including a plurality of quantum dot phosphors with different emission peak wavelengths in fluorescent plate 20. FIG. 3 shows a relationship between examples of lighting apparatus 100 and color rendering index Ri (i is an integer between 1 and 15). FIG. 4 shows a relationship between examples of lighting apparatus 100 and properties of the quantum dots used in each of the examples. Note that in FIGS. 3 and 4, comparative examples resulting from careful study by the inventors are illustrated in addition to Examples 1 to 8 with color rendering indices R1 to R15, each having a high value. In FIG. 3, cells that are hatched have a color rendering index of less than 90, and cells that are not hatched have a color rendering index of 90 or higher.

### COMPARATIVE EXAMPLES 1 TO 6

Lighting apparatus 100 according to Comparative Examples 1 to 6 will be explained first. In lighting apparatus 100 according to Comparative Example 1, two types of quantum dot phosphors are included in fluorescent plate 20: quantum dot phosphors with an emission peak wavelength of 555 nm and quantum dot phosphors with an emission peak wavelength of 630 nm.

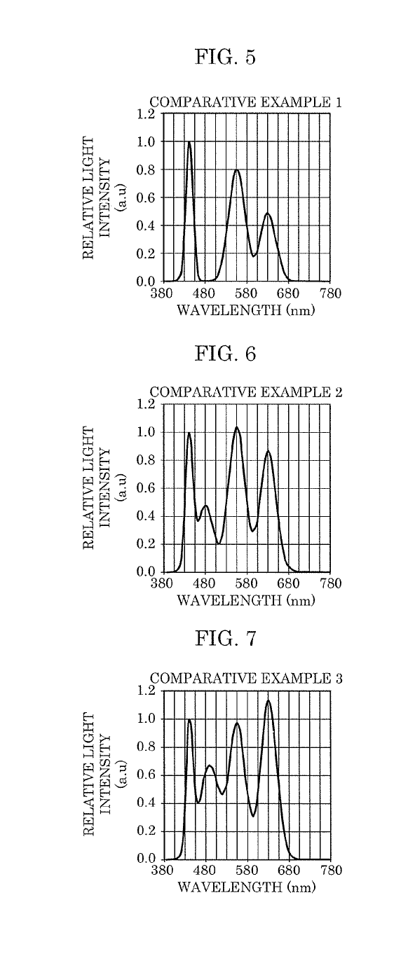

The quantum dot phosphors with the emission peak wavelength of 555 nm have a light intensity half width of 45 nm and an intensity ratio of 46. The quantum dot phosphors with the emission peak wavelength of 630 nm have a light intensity half width of 45 nm and an intensity ratio of 28. Note that this intensity ratio is a relative light intensity and that in lighting apparatus 100 according to Comparative Example 1, blue light with an emission peak wavelength of 441.5 nm emitted by light emitting unit 10 has a light intensity half width of 20 nm and an intensity ratio of 26. FIG. 5 shows an emission spectrum of lighting apparatus 100 according to Comparative Example 1. Emission light of lighting apparatus 100 according to Comparative Example 1 has a color temperature of 4981.3 K and a Duv value of 0.5.

In lighting apparatus 100 according to Comparative Example 2, three types of quantum dot phosphors are included in fluorescent plate 20: quantum dot phosphors with an emission peak wavelength of 480 nm, quantum dot phosphors with an emission peak wavelength of 555 nm, and quantum dot phosphors with an emission peak wavelength of 630 nm.

The quantum dot phosphors with the emission peak wavelength of 480 nm have a light intensity half width of 45 nm and an intensity ratio of 28. The quantum dot phosphors with the emission peak wavelength of 555 nm have a light intensity half width of 45 nm and an intensity ratio of 62. The quantum dot phosphors with the emission peak wavelength of 630 nm have a light intensity half width of 45 nm and an intensity ratio of 51. In lighting apparatus 100 according to Comparative Example 2, blue light with an emission peak wavelength of 441.5 nm emitted by light emitting unit 10 has a light intensity half width of 20 nm and an intensity ratio of 25. FIG. 6 shows an emission spectrum of lighting apparatus 100 according to Comparative Example 2. Emission light of lighting apparatus 100 according to Comparative Example 2 has a color temperature of 4987.9 K and a Duv value of −0.3.

In lighting apparatus 100 according to Comparative Example 3, four types of quantum dot phosphors are included in fluorescent plate 20: quantum dot phosphors with an emission peak wavelength of 480 nm, quantum dot phosphors with an emission peak wavelength of 505 nm, quantum dot phosphors with an emission peak wavelength of 555 nm, and quantum dot phosphors with an emission peak wavelength of 630 nm.

The quantum dot phosphors with the emission peak wavelength of 480 nm have a light intensity half width of 45 nm and an intensity ratio of 32. The quantum dot phosphors with the emission peak wavelength of 505 nm have a light intensity half width of 45 nm and an intensity ratio of 20. The quantum dot phosphors with the emission peak wavelength of 555 nm have a light intensity half width of 45 nm and an intensity ratio of 62. The quantum dot phosphors with the emission peak wavelength of 630 nm have a light intensity half width of 45 nm and an intensity ratio of 73. In lighting apparatus 100 according to Comparative Example 3, blue light with an emission peak wavelength of 441.5 nm emitted by light emitting unit 10 has a light intensity half width of 20 nm and an intensity ratio of 27. FIG. 7 shows an emission spectrum of lighting apparatus 100 according to Comparative Example 3. Emission light of lighting apparatus 100 according to Comparative Example 3 has a color temperature of 4953.3 K and a Duv value of −0.6.

In lighting apparatus 100 according to Comparative Example 4, five types of quantum dot phosphors are included in fluorescent plate 20: quantum dot phosphors with an emission peak wavelength of 480 nm, quantum dot phosphors with an emission peak wavelength of 505 nm, quantum dot phosphors with an emission peak wavelength of 530 nm, quantum dot phosphors with an emission peak wavelength of 555 nm, and quantum dot phosphors with an emission peak wavelength of 630 nm.

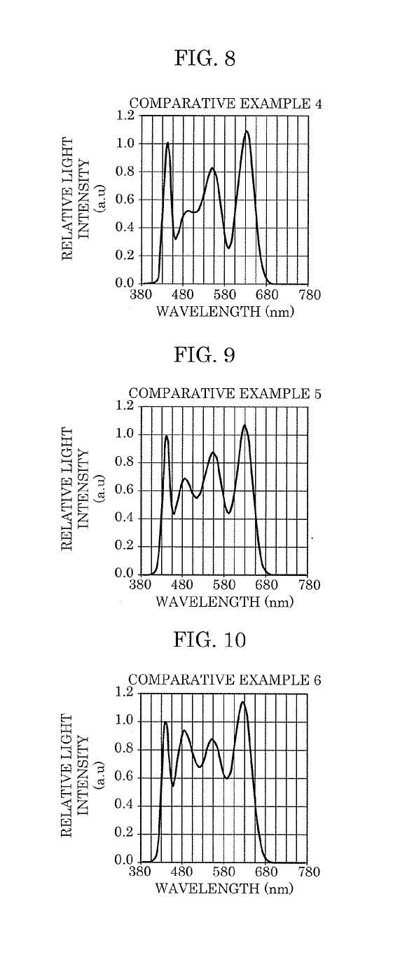

The quantum dot phosphors with the emission peak wavelength of 480 nm have a light intensity half width of 45 nm and an intensity ratio of 32. The quantum dot phosphors with the emission peak wavelength of 505 nm have a light intensity half width of 45 nm and an intensity ratio of 20. The quantum dot phosphors with the emission peak wavelength of 530 nm have a light intensity half width of 45 nm and an intensity ratio of 20. The quantum dot phosphors with the emission peak wavelength of 555 nm have a light intensity half width of 45 nm and an intensity ratio of 61. The quantum dot phosphors with the emission peak wavelength of 630 nm have a light intensity half width of 45 nm and an intensity ratio of 95. In lighting apparatus 100 according to Comparative Example 4, blue light with an emission peak wavelength of 441.5 nm emitted by light emitting unit 10 has a light intensity half width of 20 nm and an intensity ratio of 38. FIG. 8 shows an emission spectrum of lighting apparatus 100 according to Comparative Example 4. Emission light of lighting apparatus 100 according to Comparative Example 4 has a color temperature of 4956.5 K and a Duv value of −0.6.

In lighting apparatus 100 according to Comparative Example 5, six types of quantum dot phosphors are included in fluorescent plate 20: quantum dot phosphors with an emission peak wavelength of 480 nm, quantum dot phosphors with an emission peak wavelength of 505 nm, quantum dot phosphors with an emission peak wavelength of 530 nm, quantum dot phosphors with an emission peak wavelength of 555 nm, quantum dot phosphors with an emission peak wavelength of 580 nm, and quantum dot phosphors with an emission peak wavelength of 630 nm.

The quantum dot phosphors with the emission peak wavelength of 480 nm have a light intensity half width of 45 nm and an intensity ratio of 50. The quantum dot phosphors with the emission peak wavelength of 505 nm have a light intensity half width of 45 nm and an intensity ratio of 20. The quantum dot phosphors with the emission peak wavelength of 530 nm have a light intensity half width of 45 nm and an intensity ratio of 20. The quantum dot phosphors with the emission peak wavelength of 555 nm have a light intensity half width of 45 nm and an intensity ratio of 61. The quantum dot phosphors with the emission peak wavelength of 580 nm have a light intensity half width of 45 nm and an intensity ratio of 20. The quantum dot phosphors with the emission peak wavelength of 630 nm have a light intensity half width of 45 nm and an intensity ratio of 95. In lighting apparatus 100 according to Comparative Example 5, blue light with an emission peak wavelength of 441.5 nm emitted by light emitting unit 10 has a light intensity half width of 20 nm and an intensity ratio of 38. FIG. 9 shows an emission spectrum of lighting apparatus 100 according to Comparative Example 5. Emission light of lighting apparatus 100 according to Comparative Example 5 has a color temperature of 4956.4 K and a Duv value of 0.0.

In lighting apparatus 100 according to Comparative Example 6, seven types of quantum dot phosphors are included in fluorescent plate 20: quantum dot phosphors with an emission peak wavelength of 480 nm, quantum dot phosphors with an emission peak wavelength of 505 nm, quantum dot phosphors with an emission peak wavelength of 530 nm, quantum dot phosphors with an emission peak wavelength of 555 nm, quantum dot phosphors with an emission peak wavelength of 580 nm, quantum dot phosphors with an emission peak wavelength of 605 nm, and quantum dot phosphors with an emission peak wavelength of 630 nm.

The quantum dot phosphors with the emission peak wavelength of 480 nm have a light intensity half width of 45 nm and an intensity ratio of 66. The quantum dot phosphors with the emission peak wavelength of 505 nm have a light intensity half width of 45 nm and an intensity ratio of 35. The quantum dot phosphors with the emission peak wavelength of 530 nm have a light intensity half width of 45 nm and an intensity ratio of 20. The quantum dot phosphors with the emission peak wavelength of 555 nm have a light intensity half width of 45 nm and an intensity ratio of 61. The quantum dot phosphors with the emission peak wavelength of 580 nm have a light intensity half width of 45 nm and an intensity ratio of 20. The quantum dot phosphors with the emission peak wavelength of 605 nm have a light intensity half width of 45 nm and an intensity ratio of 20. The quantum dot phosphors with the emission peak wavelength of 630 nm have a light intensity half width of 45 nm and an intensity ratio of 95. In lighting apparatus 100 according to Comparative Example 6, blue light with an emission peak wavelength of 441.5 nm emitted by light emitting unit 10 has a light intensity half width of 20 nm and an intensity ratio of 38. FIG. 10 shows an emission spectrum of lighting apparatus 100 according to Comparative Example 6. Emission light of lighting apparatus 100 according to Comparative Example 6 has a color temperature of 4957.7 K and a Duv value of −0.6.

In lighting apparatus 100 according to Comparative Examples 1 to 6 described above, color rendering indices R1 to R15 partially include comparatively low values. However, in lighting apparatus 100 according to Comparative Examples 3 to 6, for example, color rendering index R12, which has a low value in regular LED lighting apparatuses, has been improved.

### EXAMPLES 1 TO 8

Lighting apparatus 100 according to Examples 1 to 8 will be described next. In lighting apparatus 100 according to Comparative Examples 1-8, six types of quantum dot phosphors are included in fluorescent plate 20: quantum dot phosphors with an emission peak wavelength of 480 nm, quantum dot phosphors with an emission peak wavelength of 505 nm, quantum dot phosphors with an emission peak wavelength of 530 nm, quantum dot phosphors with an emission peak wavelength of 555 nm, quantum dot phosphors with an emission peak wavelength of 580 nm, and quantum dot phosphors with an emission peak wavelength of 630 nm.

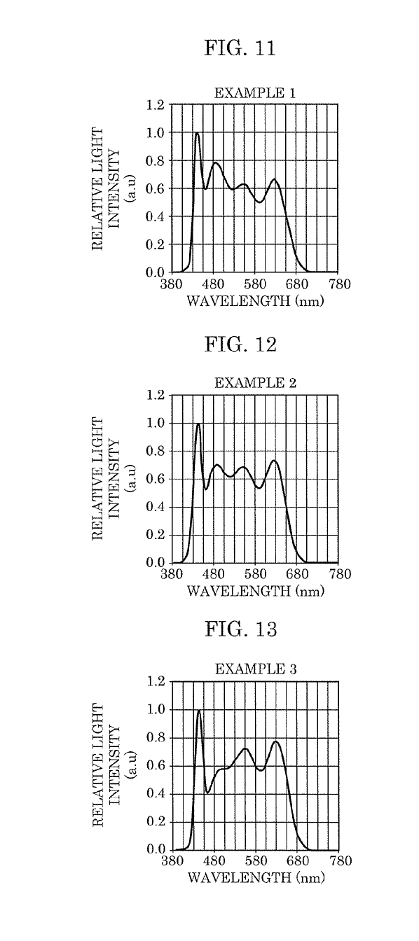

In lighting apparatus 100 according to Example 1, the quantum dot phosphors with the emission peak wavelength of 480 nm have a light intensity half width of 60 nm and an intensity ratio of 100. The quantum dot phosphors with the emission peak wavelength of 505 nm have a light intensity half width of 60 nm and an intensity ratio of 20. The quantum dot phosphors with the emission peak wavelength of 530 nm have a light intensity half width of 60 nm and an intensity ratio of 20. The quantum dot phosphors with the emission peak wavelength of 555 nm have a light intensity half width of 60 nm and an intensity ratio of 63. The quantum dot phosphors with the emission peak wavelength of 580 nm have a light intensity half width of 60 nm and an intensity ratio of 23. The quantum dot phosphors with the emission peak wavelength of 630 nm have a light intensity half width of 60 nm and an intensity ratio of 95. In lighting apparatus 100 according to Example 1, blue light with an emission peak wavelength of 441.5 nm emitted by light emitting unit 10 has a light intensity half width of 20 nm and an intensity ratio of 40. FIG. 11 shows an emission spectrum of lighting apparatus 100 according to Example 1. Emission light of lighting apparatus 100 according to Example 1 has a color temperature of 6522.2 K and a Duv value of 0.6.

In lighting apparatus 100 according to Example 2, the quantum dot phosphors with the emission peak wavelength of 480 nm have a light intensity half width of 60 nm and an intensity ratio of 75. The quantum dot phosphors with the emission peak wavelength of 505 nm have a light intensity half width of 60 nm and an intensity ratio of 20. The quantum dot phosphors with the emission peak wavelength of 530 nm have a light intensity half width of 60 nm and an intensity ratio of 20. The quantum dot phosphors with the emission peak wavelength of 555 nm have a light intensity half width of 60 nm and an intensity ratio of 63. The quantum dot phosphors with the emission peak wavelength of 580 nm have a light intensity half width of 60 nm and an intensity ratio of 20. The quantum dot phosphors with the emission peak wavelength of 630 nm have a light intensity half width of 60 nm and an intensity ratio of 95. In lighting apparatus 100 according to Example 2, blue light with an emission peak wavelength of 441.5 nm emitted by light emitting unit 10 has a light intensity half width of 20 nm and an intensity ratio of 38. FIG. 12 shows an emission spectrum of lighting apparatus 100 according to Example 2. Emission light of lighting apparatus 100 according to Example 2 has a color temperature of 5716.4 K and a Duv value of 0.3.

In lighting apparatus 100 according to Example 3, the quantum dot phosphors with the emission peak wavelength of 480 nm have a light intensity half width of 60 nm and an intensity ratio of 51. The quantum dot phosphors with the emission peak wavelength of 505 nm have a light intensity half width of 60 nm and an intensity ratio of 20. The quantum dot phosphors with the emission peak wavelength of 530 nm have a light intensity half width of 60 nm and an intensity ratio of 20. The quantum dot phosphors with the emission peak wavelength of 555 nm have a light intensity half width of 60 nm and an intensity ratio of 63. The quantum dot phosphors with the emission peak wavelength of 580 nm have a light intensity half width of 60 nm and an intensity ratio of 20. The quantum dot phosphors with the emission peak wavelength of 630 nm have a light intensity half width of 60 nm and an intensity ratio of 95. In lighting apparatus 100 according to Example 3, blue light with an emission peak wavelength of 441.5 nm emitted by light emitting unit 10 has a light intensity half width of 20 nm and an intensity ratio of 38. FIG. 13 shows an emission spectrum of lighting apparatus 100 according to Example 3. Emission light of lighting apparatus 100 according to Example 3 has a color temperature of 5042.1 K and a Duv value of −0.4.

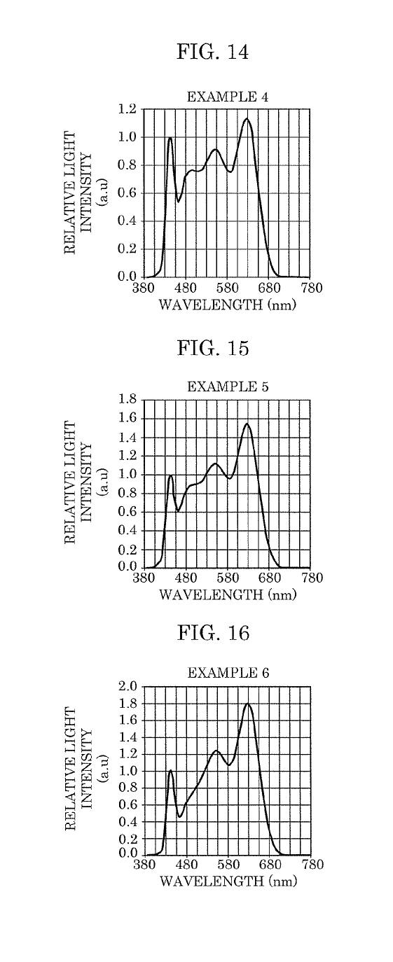

In lighting apparatus 100 according to Example 4, the quantum dot phosphors with the emission peak wavelength of 480 nm have a light intensity half width of 60 nm and an intensity ratio of 69. The quantum dot phosphors with the emission peak wavelength of 505 nm have a light intensity half width of 60 nm and an intensity ratio of 19. The quantum dot phosphors with the emission peak wavelength of 530 nm have a light intensity half width of 60 nm and an intensity ratio of 32. The quantum dot phosphors with the emission peak wavelength of 555 nm have a light intensity half width of 60 nm and an intensity ratio of 69. The quantum dot phosphors with the emission peak wavelength of 580 nm have a light intensity half width of 60 nm and an intensity ratio of 26. The quantum dot phosphors with the emission peak wavelength of 630 nm have a light intensity half width of 60 nm and an intensity ratio of 133. In lighting apparatus 100 according to Example 4, blue light with an emission peak wavelength of 441.5 nm emitted by light emitting unit 10 has a light intensity half width of 20 nm and an intensity ratio of 34. FIG. 14 shows an emission spectrum of lighting apparatus 100 according to Example 4. Emission light of lighting apparatus 100 according to Example 4 has a color temperature of 4506.6 K and a Duv value of −0.4.

In lighting apparatus 100 according to Example 5, the quantum dot phosphors with the emission peak wavelength of 480 nm have a light intensity half width of 60 nm and an intensity ratio of 75. The quantum dot phosphors with the emission peak wavelength of 505 nm have a light intensity half width of 60 nm and an intensity ratio of 18. The quantum dot phosphors with the emission peak wavelength of 530 nm have a light intensity half width of 60 nm and an intensity ratio of 43. The quantum dot phosphors with the emission peak wavelength of 555 nm have a light intensity half width of 60 nm and an intensity ratio of 75. The quantum dot phosphors with the emission peak wavelength of 580 nm have a light intensity half width of 60 nm and an intensity ratio of 32. The quantum dot phosphors with the emission peak wavelength of 630 nm have a light intensity half width of 60 nm and an intensity ratio of 170. In lighting apparatus 100 according to Example 5, blue light with an emission peak wavelength of 441.5 nm emitted by light emitting unit 10 has a light intensity half width of 20 nm and an intensity ratio of 30. FIG. 15 shows an emission spectrum of lighting apparatus 100 according to Example 5. Emission light of lighting apparatus 100 according to Example 5 has a color temperature of 4033.8 K and a Duv value of 0.3.

In lighting apparatus 100 according to Example 6, the quantum dot phosphors with the emission peak wavelength of 480 nm have a light intensity half width of 60 nm and an intensity ratio of 45. The quantum dot phosphors with the emission peak wavelength of 505 nm have a light intensity half width of 60 nm and an intensity ratio of 18. The quantum dot phosphors with the emission peak wavelength of 530 nm have a light intensity half width of 60 nm and an intensity ratio of 43. The quantum dot phosphors with the emission peak wavelength of 555 nm have a light intensity half width of 60 nm and an intensity ratio of 75. The quantum dot phosphors with the emission peak wavelength of 580 nm have a light intensity half width of 60 nm and an intensity ratio of 32. The quantum dot phosphors with the emission peak wavelength of 630 nm have a light intensity half width of 60 nm and an intensity ratio of 180. In lighting apparatus 100 according to Example 6, blue light with an emission peak wavelength of 441.5 nm emitted by light emitting unit 10 has a light intensity half width of 20 nm and an intensity ratio of 30. FIG. 16 shows an emission spectrum of lighting apparatus 100 according to Example 6. Emission light of lighting apparatus 100 according to Example 6 has a color temperature of 3536.0 K and a Duv value of 0.4.

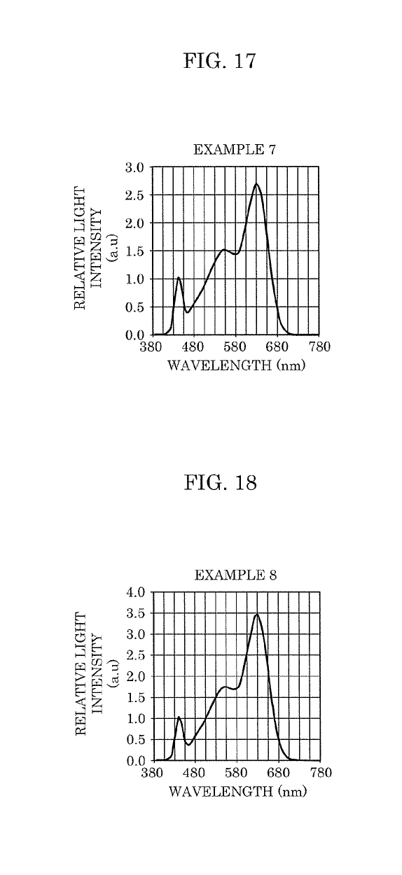

In lighting apparatus 100 according to Example 7, the quantum dot phosphors with the emission peak wavelength of 480 nm have a light intensity half width of 60 nm and an intensity ratio of 35. The quantum dot phosphors with the emission peak wavelength of 505 nm have a light intensity half width of 60 nm and an intensity ratio of 18. The quantum dot phosphors with the emission peak wavelength of 530 nm have a light intensity half width of 60 nm and an intensity ratio of 63. The quantum dot phosphors with the emission peak wavelength of 555 nm have a light intensity half width of 60 nm and an intensity ratio of 75. The quantum dot phosphors with the emission peak wavelength of 580 nm have a light intensity half width of 60 nm and an intensity ratio of 50. The quantum dot phosphors with the emission peak wavelength of 630 nm have a light intensity half width of 60 nm and an intensity ratio of 260. In lighting apparatus 100 according to Example 7, blue light with an emission peak wavelength of 441.5 nm emitted by light emitting unit 10 has a light intensity half width of 20 nm and an intensity ratio of 30. FIG. 17 shows an emission spectrum of lighting apparatus 100 according to Example 7. Emission light of lighting apparatus 100 according to Example 7 has a color temperature of 2969.1 K and a Duv value of −0.5.

In lighting apparatus 100 according to Example 8, the quantum dot phosphors with the emission peak wavelength of 480 nm have a light intensity half width of 60 nm and an intensity ratio of 25. The quantum dot phosphors with the emission peak wavelength of 505 nm have a light intensity half width of 60 nm and an intensity ratio of 17. The quantum dot phosphors with the emission peak wavelength of 530 nm have a light intensity half width of 60 nm and an intensity ratio of 60. The quantum dot phosphors with the emission peak wavelength of 555 nm have a light intensity half width of 60 nm and an intensity ratio of 70. The quantum dot phosphors with the emission peak wavelength of 580 nm have a light intensity half width of 60 nm and an intensity ratio of 46. The quantum dot phosphors with the emission peak wavelength of 630 nm have a light intensity half width of 60 nm and an intensity ratio of 277. In lighting apparatus 100 according to Example 8, blue light with an emission peak wavelength of 441.5 nm emitted by light emitting unit 10 has a light intensity half width of 20 nm and an intensity ratio of 25. FIG. 18 shows an emission spectrum of lighting apparatus 100 according to Example 8. Emission light of lighting apparatus 100 according to Example 8 has a color temperature of 2715.2 K and a Duv value of −0.7.

In lighting apparatus 100 according to Examples 1 to 8 described above, color rendering indices R1 to R15 have no values below 79. In other words, in lighting apparatus 100 according to Examples 1 to 8, color rendering indices R1 to R15 all have values of at least 79. In other words, it is possible to say that lighting apparatus 100 according to Examples 1 to 8 has enhanced color reproduction.

The emission spectra of the emission light of lighting apparatus 100 according to Examples 1 to 8 have a first peak in a wavelength ranging from 420 nm to 460 nm, a second peak in the wavelength ranging from 530 nm to 580 nm, a third peak in the wavelength ranging from 605 nm to 655 nm, a first trough in the wavelength ranging from 440 nm to 480 nm, and a second trough in the wavelength ranging from 555 nm to 605 nm. The first trough ranges from 440 nm to 480 nm and is located, more specifically, in wavelength range longer than the wavelength of the first peak. The second trough ranges from 555 nm to 605 nm and is located, more specifically, in wavelength range longer than the wavelength of the second peak.

The first peak lies in the blue wavelength range, the second peak lies in the green wavelength range, and the third peak lies in the red wavelength range. The first trough lies in the blue wavelength range and the second trough lies in the orange wavelength range.

Note that the first peak and second peak indicate points that have the highest local light intensity values in the emission spectrum (i.e., local maximum). The first peak and second peak may also be referred to as first protrusion and second protrusion. The first trough, second trough, and a third trough indicate points that have the lowest local light intensity values in the emission spectrum (i.e., local minimum). The first trough, second trough, and third through may also be referred to as first recess, second recess, and third recess.

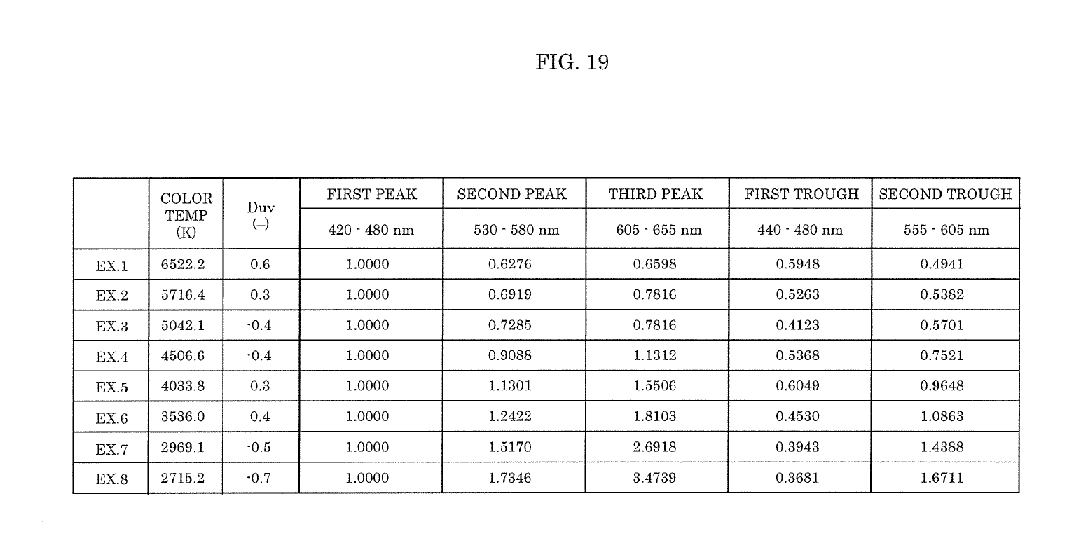

FIG. 19 shows the light intensity ratio of the second peak, third peak, first trough, and second trough to the first peak. In other words, FIG. 19 shows the light intensity of the second peak, third peak, first trough, and second trough when the light intensity of the first peak is 1.

As illustrated in FIGS. 11 to 19, in the emission spectrum of the emission light of lighting apparatus 100 according to Examples 1 to 8, the light intensity is at least 0.35 and no less than 0.35 in the wavelength range longer than the wavelength of the first peak and shorter than the wavelength of the third peak when the light intensity of the first peak is 1. In other words, there is no light intensity around the extremely short wavelength range. This makes it possible for color rendering indices R1 to R15 to all have comparatively high values.

Note that in lighting apparatus 100 according to Examples 1 to 8, quantum dot phosphors with a greater half width than in lighting apparatus 100 according to Comparative Examples 1 to 6 are used. In lighting apparatus 100 according to Examples 1 to 8, to be specific, quantum dot phosphors with a half width of at least 60 nm are used. This makes it possible to easily reduce the light intensity at the extremely short wavelength range of the emission spectrum. In other words, the emission spectrum as described in the above Examples 1 to 8 can easily be achieved. Note that the emission spectrum as described in the above Examples 1 to 8 may also have quantum dot phosphors with a half width of less than 60 nm.

The emission spectrum described in Examples 1 to 8 has the first peak, second peak, and third peak, but may also have other peaks than these three peaks. Similarly, the emission spectrum as described in Examples 1 to 8 may have the first trough and second trough, but may also have other troughs than these two troughs.

(Requirements for Lighting Apparatus with High Color Rendering Index Values)

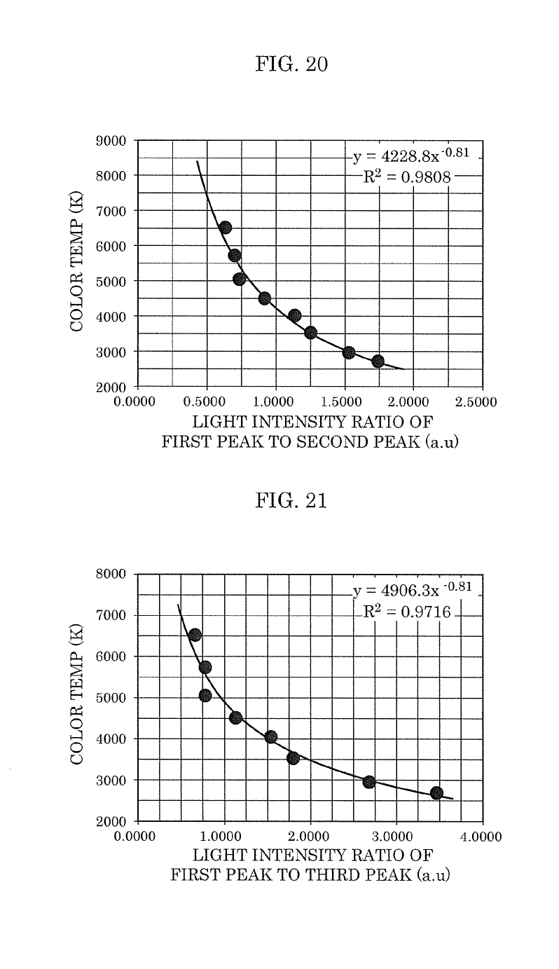

The requirements for a lighting apparatus with high color rendering index values will be described. FIG. 20 is a plotted graph of the color temperature and the light intensity ratio of the second peak to the first peak based on data in FIG. 19. The light intensity ratio of the second peak to the first peak may also be referred to as relative light intensity of the second peak. As illustrated in FIG. 20, the color temperature and the light intensity ratio of the second peak to the first peak have a strong correlation in which a correlation coefficient is R²=0.9808. An approximation curve showing a relationship between the color temperature and the light intensity ratio of the second peak to the first peak is expressed with the formula in the upper right corner of FIG. 20.

Similarly, FIG. 21 is a plotted graph of the color temperature and the light intensity ratio of the third peak to the first peak based on the data in FIG. 19. The light intensity ratio of the third peak to the first peak may also be referred to as relative light intensity of the third peak. As illustrated in FIG. 21, the color temperature and the light intensity ratio of the third peak to the first peak have a strong correlation in which the correlation coefficient is R²=0.9716. An approximation curve showing a relationship between the color temperature and the light intensity ratio of the third peak to the first peak is expressed with the formula in the upper right corner of FIG. 21.

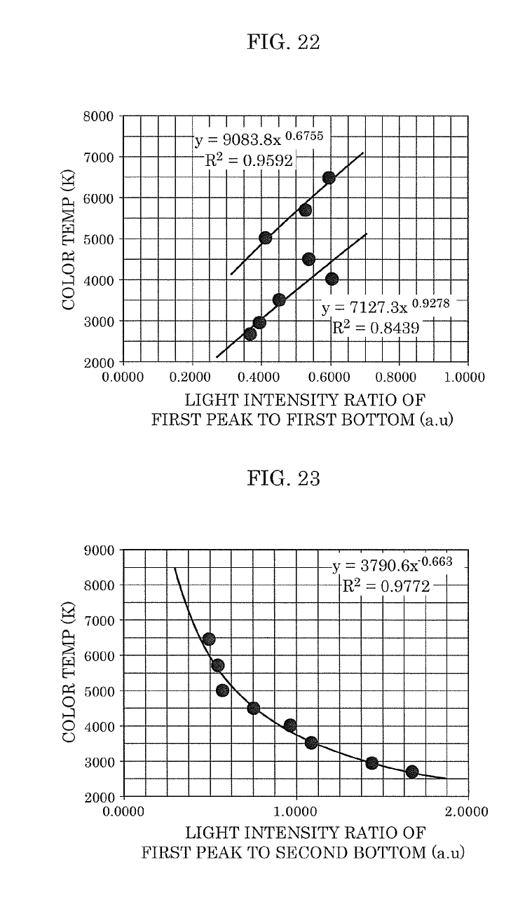

FIG. 22 is a plotted graph of the color temperature and the light intensity ratio of the first trough to the first peak based on the data in FIG. 19. The light intensity ratio of the first trough to the first peak may also be referred to as relative light intensity of the first trough. As illustrated in FIG. 21, the color temperature and the light intensity ratio of the first trough to the first peak have a strong correlation when the color temperatures of 5000 K and above and the color temperatures of 4500 K and below are considered separately. An approximation curve showing a relationship between the color temperature and the light intensity ratio of the first trough to the first peak is expressed with the formula in FIG. 22.

Moreover, FIG. 23 is a plotted graph of the color temperature and the light intensity ratio of the second trough to the first peak based on the data in FIG. 19. The light intensity ratio of the second trough to the first peak may also be referred to as relative light intensity of the second trough. As illustrated in FIG. 22, the color temperature and the light intensity ratio of the second trough to the first peak have a strong correlation in which the correlation coefficient is R²=0.9772. An approximation curve showing a relationship between the color temperature and the light intensity ratio of the second trough to the first peak is expressed with the formula in the upper right corner of FIG. 23.

In this manner, the inventors have identified a strong correlation between the color temperature and each of the relative light intensity of the second peak, the relative light intensity of the third peak, the relative light intensity of the first trough, and the relative light intensity of the second trough in lighting apparatus 100 in which color rendering indices R1 to R15 all have comparatively high values. Such a correlation makes it possible to specify requirements that the emission spectra must meet in order to raise all color rendering indices R1 to R15 in lighting apparatus 100 with a certain color temperature.

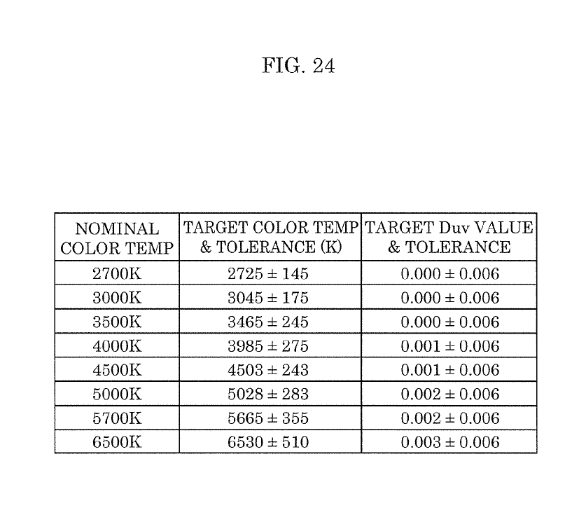

For example, FIG. 24 shows the color temperature standard established by the ANSI. As illustrated in FIG. 24, in the color temperature standard established by the ANSI, nominal color temperatures of the emission light of lighting apparatus 100 and a corresponding tolerance of the nominal color temperatures (i.e., concrete range of the color temperatures) are established. By using the formulas in FIGS. 20 to 23 and the corresponding tolerance of the nominal color temperatures in FIG. 24, the requirements that the emission spectra must meet in order to raise all color rendering indices R1 to R15 are specified.

(Requirements to be Met by Lighting Apparatus with Emission Light Having Color Temperature of 6500 K)

For example, lighting apparatus 100 with a nominal color temperature of 6500 K has, to be specific, emission light with a color temperature of 6530±510 K. In order to raise all color rendering indices R1 to R15, the second peak in the emission spectrum of lighting apparatus 100 with a nominal color temperature of 6500 K may have a relative light intensity in the range of 6530±510 K using the formula in FIG. 20. To be specific, the light intensity ratio of the second peak to the first peak in the emission spectrum may be at least 0.53 and less than 0.65.

Similarly, the third peak in the emission spectrum of lighting apparatus 100 with a nominal color temperature of 6500 K may have a relative light intensity in the range of 6530±510 K using the formula in FIG. 21. To be specific, the light intensity ratio of the third peak to the first peak in the emission spectrum may be at least 0.49 and less than 0.66.

The first trough in the emission spectrum of lighting apparatus 100 with a nominal color temperature of 6500 K may have a relative light intensity in the range of 6530±510 K using the formula in FIG. 22. To be specific, the light intensity ratio of the first trough to the first peak in the emission spectrum may be at least 0.54 and less than 0.69.

The second trough in the emission spectrum of lighting apparatus 100 with a nominal color temperature of 6500 K may have a relative light intensity in the range of 6530±510 K using the formula in FIG. 23. To be specific, the light intensity ratio of the second trough to the first peak in the emission spectrum may be at least 0.39 and less than 0.50.

(Requirements to be Met by Lighting Apparatus with Emission Light Having Color Temperature of 5700 K)

For example, lighting apparatus 100 with a nominal color temperature of 5700 K has, to be specific, emission light with a color temperature of 5665±355 K. In order to raise all color rendering indices R1 to R15, the second peak in the emission spectrum of lighting apparatus 100 with a nominal color temperature of 5700 K may have a relative light intensity in the range of 5665±355 K using the formula in FIG. 20. To be specific, the light intensity ratio of the second peak to the first peak in the emission spectrum may be at least 0.65 and less than 0.76.

Similarly, the third peak in the emission spectrum of lighting apparatus 100 with a nominal color temperature of 5700 K may have a relative light intensity in the range of 5665±355 K using the formula in FIG. 21. To be specific, the light intensity ratio of the third peak to the first peak in the emission spectrum may be at least 0.66 and less than 0.85.

The first trough in the emission spectrum of lighting apparatus 100 with a nominal color temperature of 5700 K may have a relative light intensity in the range of 5665±355 K using the formula in FIG. 22. To be specific, the light intensity ratio of the first trough to the first peak in the emission spectrum may be at least 0.45 and less than 0.54.

The second trough in the emission spectrum of lighting apparatus 100 with a nominal color temperature of 5700 K may have a relative light intensity in the range of 5665±355 K using the formula in FIG. 23. To be specific, the light intensity ratio of the second trough to the first peak in the emission spectrum may be at least 0.50 and less than 0.60.

(Requirements to be Met by Lighting Apparatus with Emission Light Having Color Temperature of 5000 K)

For example, lighting apparatus 100 with a nominal color temperature of 5000 K has, to be specific, emission light with a color temperature of 5028±283 K. In order to raise all color rendering indices R1 to R15, the second peak in the emission spectrum of lighting apparatus 100 with a nominal color temperature of 5000 K may have a relative light intensity in the range of 5028±283 K using the formula in FIG. 20. To be specific, the light intensity ratio of the second peak to the first peak in the emission spectrum may be at least 0.76 and less than 0.87.

Similarly, the third peak in the emission spectrum of lighting apparatus 100 with a nominal color temperature of 5000 K may have a relative light intensity in the range of 5028±283 K using the formula in FIG. 21. To be specific, the light intensity ratio of the third peak to the first peak in the emission spectrum may be at least 0.85 and less than 1.10.

The first trough in the emission spectrum of lighting apparatus 100 with a nominal color temperature of 5000 K may have a relative light intensity in the range of 5028±283 K using the formula in FIG. 22. To be specific, the light intensity ratio of the first trough to the first peak in the emission spectrum may be at least 0.38 and less than 0.45.

The second trough in the emission spectrum of lighting apparatus 100 with a nominal color temperature of 5000 K may have a relative light intensity in the range of 5028±283 K using the formula in FIG. 23. To be specific, the light intensity ratio of the second trough to the first peak in the emission spectrum may be at least 0.6 and less than 0.71.

(Requirements to be Met by Lighting Apparatus with Emission Light Having Color Temperature of 4500 K)

For example, lighting apparatus 100 with a nominal color temperature of 4500 K has, to be specific, emission light with a color temperature of 4503±243 K. In order to raise all color rendering indices

R1 to R15, the second peak in the emission spectrum of lighting apparatus 100 with a nominal color temperature of 4500 K may have a relative light intensity in the range of 4503±243 K using the formula in FIG. 20. To be specific, the light intensity ratio of the second peak to the first peak in the emission spectrum may be at least 0.87 and less than 0.99.

Similarly, the third peak in the emission spectrum of lighting apparatus 100 with a nominal color temperature of 4500 K may have a relative light intensity in the range of 4503±243 K using the formula in FIG. 21. To be specific, the light intensity ratio of the third peak to the first peak in the emission spectrum may be at least 1.10 and less than 1.33.

The first trough in the emission spectrum of lighting apparatus 100 with a nominal color temperature of 4500 K may have a relative light intensity in the range of 4503±243 K using the formula in FIG. 22. To be specific, the light intensity ratio of the first trough to the first peak in the emission spectrum may be at least 0.57 and less than 0.65.

The second trough in the emission spectrum of lighting apparatus 100 with a nominal color temperature of 4500 K may have a relative light intensity in the range of 4503±243 K using the formula in FIG. 23. To be specific, the light intensity ratio of the second trough to the first peak in the emission spectrum may be at least 0.71 and less than 0.84.

(Requirements to be Met by Lighting Apparatus with Emission Light Having Color Temperature of 4000 K)

For example, lighting apparatus 100 with a nominal color temperature of 4000 K has, to be specific, emission light with a color temperature of 3985±275 K. In order to raise all color rendering indices R1 to R15, the second peak in the emission spectrum of lighting apparatus 100 with a nominal color temperature of 4000 K may have a relative light intensity in the range of 3985±275 K using the formula in FIG. 20. To be specific, the light intensity ratio of the second peak to the first peak in the emission spectrum may be at least 0.99 and less than 1.18.

Similarly, the third peak in the emission spectrum of lighting apparatus 100 with a nominal color temperature of 4000 K may have a relative light intensity in the range of 3985±275 K using the formula in FIG. 21. To be specific, the light intensity ratio of the third peak to the first peak in the emission spectrum may be at least 1.33 and less than 1.75.

The first trough in the emission spectrum of lighting apparatus 100 with a nominal color temperature of 4000 K may have a relative light intensity in the range of 3985±275 K using the formula in FIG. 22. To be specific, the light intensity ratio of the first trough to the first peak in the emission spectrum may be at least 0.49 and less than 0.57.

The second trough in the emission spectrum of lighting apparatus 100 with a nominal color temperature of 4000 K may have a relative light intensity in the range of 3985±275 K using the formula in FIG. 23. To be specific, the light intensity ratio of the second trough to the first peak in the emission spectrum may be at least 0.84 and less than 1.03.

(Requirements to be Met by Lighting Apparatus with Emission Light Having Color Temperature of 3500 K)

For example, lighting apparatus 100 with a nominal color temperature of 3500 K has, to be specific, emission light with a color temperature of 3465±245 K. In order to raise all color rendering indices R1 to R15, the second peak in the emission spectrum of lighting apparatus 100 with a nominal color temperature of 3500 K may have a relative light intensity in the range of 3465±245 K using the formula in FIG. 20. To be specific, the light intensity ratio of the second peak to the first peak in the emission spectrum may be at least 1.18 and less than 1.40.

Similarly, the third peak in the emission spectrum of lighting apparatus 100 with a nominal color temperature of 3500 K may have a relative light intensity in the range of 3465±245 K using the formula in FIG. 21. To be specific, the light intensity ratio of the third peak to the first peak in the emission spectrum may be at least 1.75 and less than 2.33.

The first trough in the emission spectrum of lighting apparatus 100 with a nominal color temperature of 3500 K may have a relative light intensity in the range of 3465±245 K using the formula in FIG. 22. To be specific, the light intensity ratio of the first trough to the first peak in the emission spectrum may be at least 0.42 and less than 0.49.

The second trough in the emission spectrum of lighting apparatus 100 with a nominal color temperature of 3500 K may have a relative light intensity in the range of 3465±245 K using the formula in FIG. 23. To be specific, the light intensity ratio of the second trough to the first peak in the emission spectrum may be at least 1.03 and less than 1.28.

(Requirements to be Met by Lighting Apparatus with Emission Light Having Color Temperature of 3000 K)

For example, lighting apparatus 100 with a nominal color temperature of 3000 K has, to be specific, emission light with a color temperature of 3045±175 K. In order to raise all color rendering indices R1 to R15, the second peak in the emission spectrum of lighting apparatus 100 with a nominal color temperature of 3000 K may have a relative light intensity in the range of 3045±175 K using the formula in FIG. 20. To be specific, the light intensity ratio of the second peak to the first peak in the emission spectrum may be at least 1.40 and less than 1.61.

Similarly, the third peak in the emission spectrum of lighting apparatus 100 with a nominal color temperature of 3000 K may have a relative light intensity in the range of 3045±175 K using the formula in FIG. 21. To be specific, the light intensity ratio of the third peak to the first peak in the emission spectrum may be at least 2.33 and less than 2.93.

The first trough in the emission spectrum of lighting apparatus 100 with a nominal color temperature of 3000 K may have a relative light intensity in the range of 3045±175 K using the formula in FIG. 22. To be specific, the light intensity ratio of the first trough to the first peak in the emission spectrum may be at least 0.38 and less than 0.42.

The second trough in the emission spectrum of lighting apparatus 100 with a nominal color temperature of 3000 K may have a relative light intensity in the range of 3045±175 K using the formula in FIG. 23. To be specific, the light intensity ratio of the second trough to the first peak in the emission spectrum may be at least 1.28 and less than 1.52.

(Requirements to be Met by Lighting Apparatus with Emission Light Having Color Temperature of 2700 K)

For example, lighting apparatus 100 with a nominal color temperature of 2700 K has, to be specific, emission light with a color temperature of 2725±145 K. In order to raise all color rendering indices R1 to R15, the second peak in the emission spectrum of lighting apparatus 100 with a nominal color temperature of 2700 K may have a relative light intensity in the range of 2725±145 K using the formula in FIG. 20. To be specific, the light intensity ratio of the second peak to the first peak in the emission spectrum may be at least 1.61 and less than 1.84.

Similarly, the third peak in the emission spectrum of lighting apparatus 100 with a nominal color temperature of 2700 K may have a relative light intensity in the range of 2725±145 K using the formula in FIG. 21. To be specific, the light intensity ratio of the third peak to the first peak in the emission spectrum may be at least 2.93 and less than 3.63.

The first trough in the emission spectrum of lighting apparatus 100 with a nominal color temperature of 2700 K may have a relative light intensity in the range of 2725±145 K using the formula in FIG. 22. To be specific, the light intensity ratio of the first trough to the first peak in the emission spectrum may be at least 0.33 and less than 0.38.

The second trough in the emission spectrum of lighting apparatus 100 with a nominal color temperature of 2700 K may have a relative light intensity in the range of 2725±145 K using the formula in FIG. 23. To be specific, the light intensity ratio of the second trough to the first peak in the emission spectrum may be at least 1.52 and less than 1.79.

### (Variation 1)

In the above Embodiment 1, the emission spectrum having the first peak, second peak, third peak, first trough, and second trough (hereinafter, also referred to as the emission spectrum according to the above Embodiment 1) is achieved using blue LED chips and the plurality of types of quantum dot phosphors with different emission peak wavelengths, but this method is an example of achieving such an emission spectrum.

For example, in order to achieve the emission spectrum according to the above Embodiment 1, ultraviolet LED chips that emit ultraviolet light with a shorter wavelength than blue light may also be used instead of to in addition to the blue LED chips. When using the ultraviolet LED chips instead of the blue LED chips, the first peak may, for example, be realized using a fluorescent substance that emits blue light.

An inorganic fluorescent substance other than the quantum dot phosphors may also be used for the light emitting particles instead of the quantum dot phosphors. Another inorganic fluorescent substance is, for example, an yttrium aluminum garnet-type fluorescent substance. Both the quantum dot phosphors and another inorganic fluorescent substance may also be used for the light emitting particles.

The emission spectrum according to the above Embodiment 1 is achieved by using six types of fluorescent substances with different emission peak wavelengths, but may also be achieved by using at least seven or less than six types of fluorescent substances with different emission peak wavelengths.

The emission peak wavelength of the quantum dot phosphors described in the above Embodiment 1 is an example. For example, quantum dot phosphors with an emission peak wavelength that differ approximately ±10 nm from the quantum dot phosphors described in the above Embodiment 1 may also be used.

The emission spectrum according to the above Embodiment 1 may also be achieved by using only the light emitting elements among the light emitting elements and light emitting particles. In other words, lighting apparatus 100 need not include wavelength-shifting material such as fluorescent plate 20. For example, the emission spectrum according to the above Embodiment 1 may also be achieved by using LED chips with different emission peak wavelengths.

### (Variation 2)

The present disclosure may also be realized as light emitting apparatus 30. Light emitting apparatus 30 is, in other words, a light emitting module used as a light source of lighting apparatus 100 according to the above Embodiment 1. The present disclosure may also be realized as the light emitting apparatus with a COB structure that emits light having the emission spectrum according to the above Embodiment 1. The light emitting apparatus with a COB structure has a structure in which the light emitting element mounted on the substrate are sealed off by a sealant including the light emitting particles. The sealant is, for example, mainly made of a light-transmissive resin such as a silicone resin.

The present disclosure may also be realized as a light emitting apparatus with a surface mount device (SMD) structure. The light emitting apparatus with an SMD structure has a structure in which SMD-type elements are mounted on the substrate. The SMD-type elements have a structure in which the light emitting elements disposed inside a container are sealed off by a sealant including light emitting particles contained in the container. The present disclosure may also be realized as a remote phosphor-type light emitting apparatus. In each case, various combinations of light emitting elements and light emitting particles used in the light emitting apparatus as described in the above Variation 1 are possible.

Note that the present disclosure may also be realized as SMD-type elements that are used in the above light emitting apparatus with an SMD structure.

### (Advantageous Effects, etc.)

Lighting apparatus 100, as described above, includes LED chips 12 that emit primary light, and phosphor particles 22 that emit secondary light by being excited with the primary light. LED chips 12 are an example of light-emitting elements, and phosphor particles 22 are an example of light-emitting particles. Lighting apparatus 100 emits light including the primary light and the secondary light. The light has an emission spectrum having a first peak in a wavelength ranging from 420 nm to 460 nm, a second peak in the wavelength ranging from 530 nm to 580 nm, a third peak in the wavelength ranging from 605 nm to 655 nm, a first trough in the wavelength ranging from 440 nm to 480 nm, and a second trough in the wavelength ranging from 555 nm to 605 nm.

This enables lighting apparatus 100 to have color rendering indices R1 to R15 all with comparatively high values as in Examples 1 to 8. In other words, the color reproduction in lighting apparatus 100 is enhanced.

For example, in the emission spectrum, the light intensity ratio of the second peak to the first peak is at least 0.53 and less than 0.65, and the light intensity ratio of the third peak to the first peak is at least 0.49 and less than 0.66. For example, the light intensity ratio of the first trough to the first peak is at least 0.54 and less than 0.69, and the light intensity ratio of the second trough to the first peak is at least 0.39 and less than 0.50. This enables lighting apparatus 100 that emits light with a nominal color temperature of 6500 K as established by the ANSI, to have color rendering indices R1 to R15 all with comparatively high values.

For example, in the emission spectrum, the light intensity ratio of the second peak to the first peak is at least 0.65 and less than 0.76, and the light intensity ratio of the third peak to the first peak is at least 0.66 and less than 0.85. For example, the light intensity ratio of the first trough to the first peak is at least 0.45 and less than 0.54, and the light intensity ratio of the second trough to the first peak is at least 0.50 and less than 0.60.

This enables lighting apparatus 100 that emits light with a nominal color temperature of 5700 K as established by the ANSI, to have color rendering indices R1 to R15 all with comparatively high values.

For example, in the emission spectrum, the light intensity ratio of the second peak to the first peak is at least 0.76 and less than 0.87, and the light intensity ratio of the third peak to the first peak is at least 0.85 and less than 1.10. For example, the light intensity ratio of the first trough to the first peak is at least 0.38 and less than 0.45 and the light intensity ratio of the second trough to the first peak is at least 0.6 and less than 0.71.

This enables lighting apparatus 100 that emits light with a nominal color temperature of 5000 K as established by the ANSI, to have color rendering indices R1 to R15 all with comparatively high values.

For example, in the emission spectrum, the light intensity ratio of the second peak to the first peak is at least 0.87 and less than 0.99, and the light intensity ratio of the third peak to the first peak is at least 1.10 and less than 1.33. For example, the light intensity ratio of the first trough to the first peak is at least 0.57 and less than 0.65, and the light intensity ratio of the second trough to the first peak is at least 0.71 and less than 0.84.

This enables lighting apparatus 100 that emits light with a nominal color temperature of 4500 K as established by the ANSI, to have color rendering indices R1 to R15 all with comparatively high values.

For example, in the emission spectrum, the light intensity ratio of the second peak to the first peak is at least 0.99 and less than 1.18, and the light intensity ratio of the third peak to the first peak is at least 1.33 and less than 1.75. For example, the light intensity ratio of the first trough to the first peak is at least 0.49 and less than 0.57, and the light intensity ratio of the second trough to the first peak is at least 0.84 and less than 1.03.

This enables lighting apparatus 100 that emits light with a nominal color temperature of 4000 K as established by the ANSI, to have color rendering indices R1 to R15 all with comparatively high values.

For example, in the emission spectrum, the light intensity ratio of the second peak to the first peak is at least 1.18 and less than 1.40, and the light intensity ratio of the third peak to the first peak is at least 1.75 and less than 2.33. For example, the light intensity ratio of the first trough to the first peak is at least 0.42 and less than 0.49, and the light intensity ratio of the second trough to the first peak is at least 1.03 and less than 1.28.

This enables lighting apparatus 100 that emits light with a nominal color temperature of 3500 K as established by the ANSI, to have color rendering indices R1 to R15 all with comparatively high values.

For example, in the emission spectrum, the light intensity ratio of the second peak to the first peak is at least 1.40 and less than 1.61, and the light intensity ratio of the third peak to the first peak is at least 2.33 and less than 2.93. For example, the light intensity ratio of the first trough to the first peak is at least 0.38 and less than 0.42, and the light intensity ratio of the second trough to the first peak is at least 1.28 and less than 1.52.

This enables lighting apparatus 100 that emits light with a nominal color temperature of 3000 K as established by the ANSI, to have color rendering indices R1 to R15 all with comparatively high values.

For example, in the emission spectrum, the light intensity ratio of the second peak to the first peak is at least 1.61 and less than 1.84, and the light intensity ratio of the third peak to the first peak is at least 2.93 and less than 3.63. For example, the light intensity ratio of the first trough to the first peak is at least 0.33 and less than 0.38, and the light intensity ratio of the second trough to the first peak is at least 1.52 and less than 1.79.

This enables lighting apparatus 100 that emits light with a nominal color temperature of 2700 K as established by the ANSI, to have color rendering indices R1 to R15 all with comparatively high values.

For example, in the emission spectrum, the light intensity is at least 0.35 in the wavelength range longer than the wavelength at the first peak and shorter than the wavelength at the third peak when a light intensity of the first peak is 1.

This enables lighting apparatus 100 to have color rendering indices R1 to R15 all with comparatively high values. In other words, the color reproduction in lighting apparatus 100 is enhanced.

Light emitting apparatus 30 includes LED chips 12 that emit the primary light, and phosphor particles 22 that emit the secondary light by being excited with the primary light. LED chips 12 are an example of light-emitting elements, and phosphor particles 22 are an example of light-emitting particles. Light emitting apparatus 30 emits light including the primary light and the secondary light. The light has an emission spectrum having the first peak in the wavelength ranging from 420 nm to 460 nm, the second peak in the wavelength ranging from 530 nm to 580 nm, the third peak in the wavelength ranging from 605 nm to 655 nm, the first trough in the wavelength ranging from 440 nm to 480 nm, and the second trough in the wavelength ranging from 555 nm to 605 nm.

This enables light emitting apparatus 30 to have color rendering indices R1 to R15 all with comparatively high values as in Examples 1 to 8. In other words, the color reproduction in light emitting apparatus 30 is enhanced.

### Embodiment 2

### (Basic Configuration)

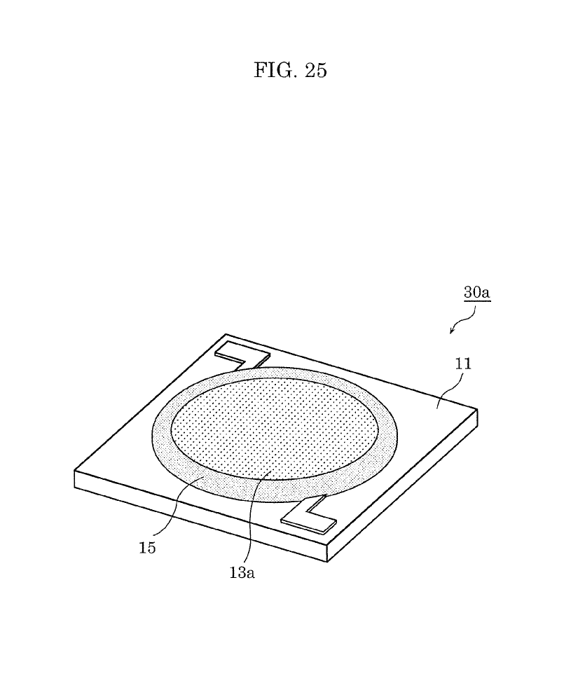

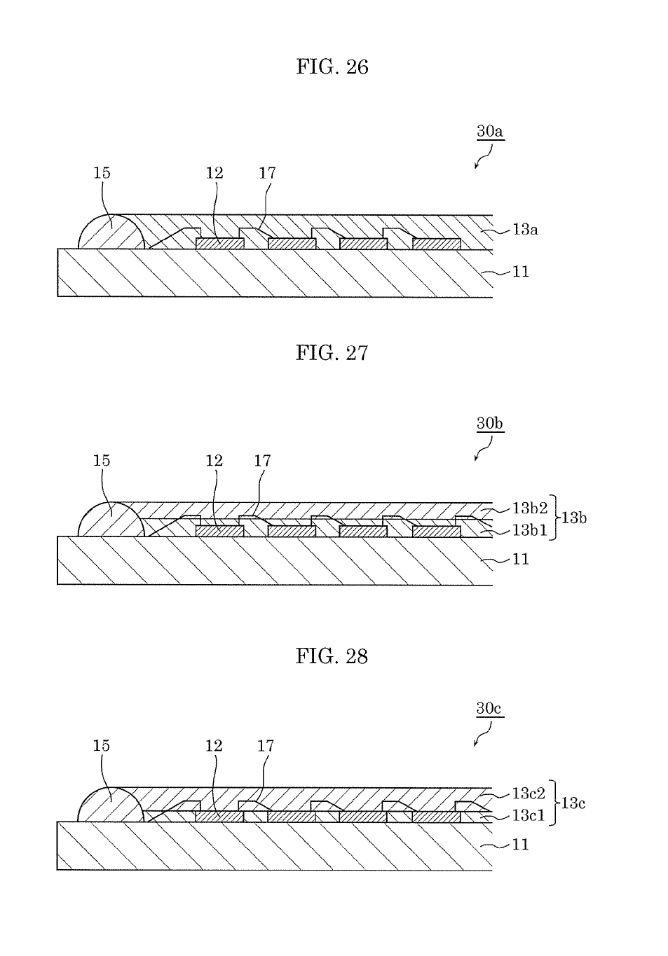

As mentioned above, the present disclosure may also be realized as the light emitting apparatus with a COB structure having the emission spectrum according to the above Embodiment 1. In Embodiment 2, a concrete configuration of a light emitting apparatus with a COB structure will be described. FIG. 25 is an external perspective view of the light emitting apparatus with a COB structure. FIG. 26 is a schematic cross-sectional view of the light emitting apparatus with a COB structure.

As illustrated in FIGS. 25 and 26, light emitting apparatus 30a includes substrate 11, LED chips 12, sealant 13a, dam material 15, and bonding wire 17.

Substrate 11 and LED chips 12 have a similar configuration as light emitting apparatus 10. LED chips 12 are mainly electrically coupled chip-to-chip by bonding wire 17. Bonding wire 17 supplies energy and is coupled electrically and structurally to LED chips 12. Note that, for example, gold (Au), silver (Ag), or copper (Cu) is used for a metal of bonding wire 17.

Dam material 15 occludes sealant 13a and is disposed on substrate 11. Dam material 15 is made of, for example, an insulating and thermosetting resin or thermoplastic resin. To be more specific, dam material 15 is made of a silicone resin, phenol resin, epoxy resin, bismaleimide-triazine resin, polyphthalamide (PPA) resin, or the like.

Dam material 15 is preferably light reflective in order to enhance the light extraction efficiency of light emitting apparatus 10. Accordingly, dam material 15 is made of a white-colored resin (so-called white resin). Note that dam material 15 may also include particles such as TiO₂, Al₂O₃, ZrO₂, and MgO in order to enhance light reflectiveness of dam material 15.

Dam material 15 in light emitting apparatus 30a is annular and surrounds LED chips 12 in a top view. Sealant 13a is disposed on an area surrounded by dam material 15. Note that dam material 15 may also be rectangular on the outside.

Sealant 13a seals off LED chips 12. Sealant 13a, more specifically, seals off LED chips 12, bonding wire 17, and a portion of wiring 16.

Sealant 13a is mainly made of a light-transmissive resin. The light-transmissive resin is, for example, a methyl-type resin, but may also be an epoxy resin, urea resin, or the like.

Sealant 13a includes phosphor particles 22. Sealant 13 includes, more specifically, a plurality of types of quantum dot phosphors with different emission peak wavelengths. With this, the emission spectrum according to the above Embodiment 1 is realized.

### (Variation 1 of Embodiment 2)

In light emitting apparatus 30a, LED chips 12 and bonding wire 17 are sealed off by sealant 13 with a single-layer structure, but LED chips 12 and bonding wire 17 may also be sealed off by a sealant with a multi-layer structure. FIG. 27 is a schematic cross-sectional view of the light emitting apparatus according to Variation 1 of Embodiment 2.

Light emitting apparatus 30b shown in FIG. 27 includes sealant 13b with a two-layered structure. Sealant 13b includes first sealing layer 13b1 that seals off LED chips 12, and second sealing layer 13b2 laminated on top of first sealing layer 13b1.

First sealing layer 13b1 and second sealing layer 13b2 are mainly made of the same material as sealant 13a. First sealing layer 13b1 is a transparent layer not including phosphor particles 22. Second sealing layer 13b2 includes phosphor particles 22. Second sealing layer 13b2 includes, more specifically, a plurality of types of quantum dot phosphors with different emission peak wavelengths. With this, the emission spectrum according to the above Embodiment 1 is achieved.

### (Variation 2 of Embodiment 2)

FIG. 28 is a schematic cross-sectional view of the light emitting apparatus according to Variation 2 of Embodiment 2. Light emitting apparatus 30c shown in FIG. 28 includes sealant 13c with a two-layered structure. Sealant 13c includes first sealing layer 13c1 that fills gaps between LED chips 12, and second sealing layer 13c2 that is laminated on LED chips 12.

First sealing layer 13c1 and second sealing layer 13c2 are mainly made of the same material as sealant 13a. First sealing layer 13c1 includes phosphor particles 22. First sealing layer 13c1 includes, more specifically, a plurality of types of quantum dot phosphors with different emission peak wavelengths. With this, the emission spectrum according to the above Embodiment 1 is achieved. Second sealing layer 13c2 is, for example, a transparent layer not including phosphor particles 22.

### (Variation 3 of Embodiment 2)

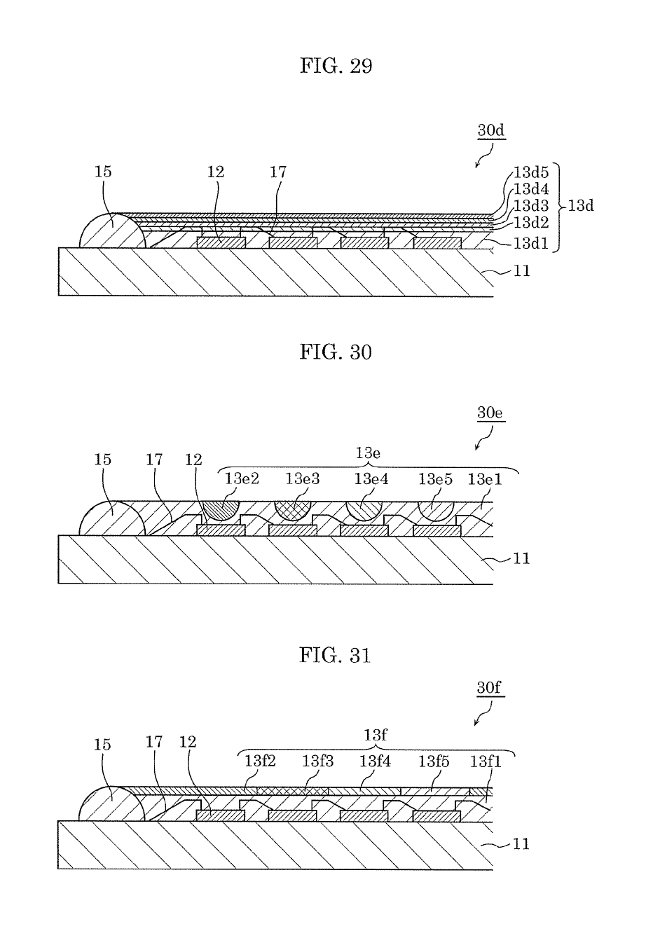

FIG. 29 is a schematic cross-sectional view of the light emitting apparatus according to Variation 3 of Embodiment 2. Light emitting apparatus 30d shown in FIG. 29 includes sealant 13d with a multi-layered structure. Sealant 13d includes sealing layer 13d1 that seals off LED chips 12, and sealing layers 13d2 to 13d5 laminated on sealing layer 13d1.

Sealing layers 13d1 to 13d5 are mainly made of the same material as sealant 13a. Sealing layer 13d1 is a transparent layer not including phosphor particles 22. Sealing layers 13d2 to 13d5 each include phosphor particles 22. Sealing layers 13d2 to 13d5 each include, more specifically, one type of the plurality of quantum dot phosphors for achieving the emission spectrum according to the above Embodiment 1. Sealing layers 13d2 to 13d5 include, for example, quantum dot phosphors with an emission wavelength peak that is longer as the sealing layers are located closer to sealing layer 13d1. To be specific, sealing layer 13d2 includes red quantum dot phosphors, sealing layer 13d3 includes yellow quantum dot phosphors, sealing layer 13d4 includes yellowgreen quantum dot phosphors, and sealing layer 13d5 includes green quantum dot phosphors. With this, absorption of fluorescence emitted from the sealing layers located downward by phosphor particles 22 in the sealing layers located upward is reduced. In other words, usage efficiency of the fluorescence is enhanced.

### (Variation 4 of Embodiment 2)

FIG. 30 is a schematic cross-sectional view of the light emitting apparatus according to Variation 4 of Embodiment 2. Light emitting apparatus 30e shown in FIG. 30 includes sealant 13e. Sealant 13e includes sealing layer 13e1 in which substantially hemispherical grooves (i.e., dot-shaped) are disposed directly above LED chips 12, and sealing layers 13e2 to 13e5 disposed in the grooves.

Sealing layers 13e1 to 13e5 are mainly made of the same material as sealant 13a. Sealing layer 13e1 is a transparent layer not including phosphor particles 22. Sealing layers 13e2 to 13e5 each include phosphor particles 22. Sealing layers 13e2 to 13e5 each include, more specifically, one type of the plurality of quantum dot phosphors for achieving the emission spectrum according to the above Embodiment 1. For example, sealing layer 13e2 includes red quantum dot phosphors, sealing layer 13e3 includes yellow quantum dot phosphors, sealing layer 13e4 includes yellowgreen quantum dot phosphors, and sealing layer 13e5 includes green quantum dot phosphors.

### (Variation 5 of Embodiment 2)

FIG. 31 is a schematic cross-sectional view of the light emitting apparatus according to Variation 5 of Embodiment 2. Light emitting apparatus 30f shown in FIG. 31 includes sealant 13f. Sealant 13f includes sealing layer 13f1 that seals off LED chips 12, and sealing layers 13f2 to 13f5 arranged along an upper surface of sealing layer f1. Sealing layers 13f2 to 13f5 are arranged on sealing layer 13f1 like a patchwork. One LED chip 12 is disposed for each sealing layer 13f2 to 13f5.

Sealing layers 13f1 to 13f5 are mainly made of the same material as sealant 13a. Sealing layer 13f1 is a transparent layer not including phosphor particles 22. Sealing layers 13f2 to 13f5 each include phosphor particles 22. Sealing layers 13f2 to 13f5 each include, more specifically, one type of the plurality of quantum dot phosphors for achieving the emission spectrum according to the above Embodiment 1. For example, sealing layer 13f2 includes red quantum dot phosphors, sealing layer 13f 3 includes yellow quantum dot phosphors, sealing layer 13f4 includes yellowgreen quantum dot phosphors, and sealing layer 13f5 includes green quantum dot phosphors.

### Other Embodiments

The light emitting apparatus and lighting apparatus according to the embodiment is described above, but the present disclosure is not limited to the above embodiment.

For example, in the above Embodiment 1, the lighting apparatus is a downlight, but the lighting apparatus in the present disclosure may also be a spotlight, ceiling light, or base light.

Moreover, the laminated structure of the light emitting apparatus described in the above Embodiment 2 is an example. In Embodiment 2, the sealant layers described as not including phosphor particles may also include phosphor particles, and the sealant layers described as including phosphor particles need not include phosphor particles. The sealant layers described as including one type of quantum dot phosphors may also include at least two types of quantum dot phosphors. In Embodiment 2, an inorganic fluorescent substance other than the quantum dot phosphors may also be used for the light emitting particles instead of the quantum dot phosphors.

Moreover, in the above embodiment, the light emitting elements used in the light emitting apparatus are LED chips. However, semiconductor light emitting elements such as semiconductor lasers or solid light emitting elements such as organic electro luminescence (EL) or inorganic EL may be used for the light emitting elements.

Additionally, forms obtained by various modifications to the embodiments that can be conceived by a person skilled in the art as well as forms realized by optionally combining components and functions in the embodiments which are within the scope of the essence of the present disclosure are included in the present disclosure. For example, the lighting apparatus or the light emitting apparatus according to the comparative examples in the above embodiments may also be included in the present disclosure.

Although only some exemplary embodiments have been described above, the score of the claims of the current disclosure is not limited to the foregoing. Those skilled in the art will readily appreciate that many modifications are possible in the exemplary embodiments and components and functions may be optionally combined in the foregoing embodiments without materially departing from the novel teachings and advantages of this invention. Accordingly, all such modifications are intended to be included within the scope of the present disclosure.

1. A lighting apparatus, comprising:
a light emitting element that emits primary light; and
light emitting particles that emit secondary light by being excited with the primary light, wherein
the lighting apparatus emits light including the primary light and the secondary light, and
the light has an emission spectrum having:
a first peak in a wavelength ranging from 420 nm to 460 nm;
a second peak in the wavelength ranging from 530 nm to 580 nm;
a third peak in the wavelength ranging from 605 nm to 655 nm;
a first trough in the wavelength ranging from 440 nm to 480 nm; and
a second trough in the wavelength ranging from 555 nm to 605 nm.

2. The lighting apparatus according to claim 1, wherein
in the emission spectrum:
a light intensity ratio of the second peak to the first peak is at least 0.53 and less than 0.65;
a light intensity ratio of the third peak to the first peak is at least 0.49 and less than 0.66;
a light intensity ratio of the first trough to the first peak is at least 0.54 and less than 0.69; and
a light intensity ratio of the second trough to the first peak is at least 0.39 and less than 0.50.

3. According to claim 1, wherein
in the emission spectrum:
a light intensity ratio of the second peak to the first peak is at least 0.65 and less than 0.76;
a light intensity ratio of the third peak to the first peak is at least 0.66 and less than 0.85;
a light intensity ratio of the first trough to the first peak is at least 0.45 and less than 0.54; and
a light intensity ratio of the second trough to the first peak is at least 0.50 and less than 0.60.

4. The lighting apparatus according to claim 1, wherein
in the emission spectrum:
a light intensity ratio of the second peak to the first peak is at least 0.76 and less than 0.87;
a light intensity ratio of the third peak to the first peak is at least 0.85 and less than 1.10;
a light intensity ratio of the first trough to the first peak is at least 0.38 and less than 0.45; and
a light intensity ratio of the second trough to the first peak is at least 0.6 and less than 0.71.

5. The lighting apparatus according to claim 1, wherein
in the emission spectrum:
a light intensity ratio of the second peak to the first peak is at least 0.87 and less than 0.99;
a light intensity ratio of the third peak to the first peak is at least 1.10 and less than 1.33;
a light intensity ratio of the first trough to the first peak is at least 0.57 and less than 0.65; and
a light intensity ratio of the second trough to the first peak is at least 0.71 and less than 0.84.

6. The lighting apparatus according to claim 1, wherein
in the emission spectrum:
a light intensity ratio of the second peak to the first peak is at least 0.99 and less than 1.18;
a light intensity ratio of the third peak to the first peak is at least 1.33 and less than 1.75;
a light intensity ratio of the first trough to the first peak is at least 0.49 and less than 0.57; and
a light intensity ratio of the second trough to the first peak is at least 0.84 and less than 1.03.

7. The lighting apparatus according to claim 1, wherein
in the emission spectrum:
a light intensity ratio of the second peak to the first peak is at least 1.18 and less than 1.40;
a light intensity ratio of the third peak to the first peak is at least 1.75 and less than 2.33;
a light intensity ratio of the first trough to the first peak is at least 0.42 and less than 0.49;and
a light intensity ratio of the second trough to the first peak is at least 1.03 and less than 1.28.

8. The lighting apparatus according to claim 1, wherein
in the emission spectrum:
a light intensity ratio of the second peak to the first peak is at least 1.40 and less than 1.61;
a light intensity ratio of the third peak to the first peak is at least 2.33 and less than 2.93;
a light intensity ratio of the first trough to the first peak is at least 0.38 and less than 0.42; and
a light intensity ratio of the second trough to the first peak is at least 1.28 and less than 1.52.

9. The lighting apparatus according to claim 1, wherein
in the emission spectrum:
a light intensity ratio of the second peak to the first peak is at least 1.61 and less than 1.84;
a light intensity ratio of the third peak to the first peak is at least 2.93 and less than 3.63;
a light intensity ratio of the first trough to the first peak is at least 0.33 and less than 0.38; and
a light intensity ratio of the second trough to the first peak is at least 1.52 and less than 1.79.

10. The lighting apparatus according to claim 1, wherein
in the emission spectrum, a light intensity is at least 0.35 in a wavelength range longer than the wavelength at the first peak and shorter than the wavelength at the third peak when a light intensity of the first peak is 1.

11. A light emitting apparatus, comprising:
a light emitting element that emits primary light; and
light emitting particles that emit secondary light by being excited with the primary light, wherein
the light emitting apparatus emits light including the primary light and the secondary light, and
the light has an emission spectrum having:
a first peak in a wavelength ranging from 420 nm to 460 nm;
a second peak in the wavelength ranging from 530 nm to 580 nm;
a third peak in the wavelength ranging from 605 nm to 655 nm;
a first trough in the wavelength ranging from 440 nm to 480 nm; and
a second trough in the wavelength ranging from 555 nm to 605 nm.
